(19) United States
(12) Patent Application Publication
(10) Pub. No.: US 2026/0144080 A1
(43) Pub. Date: May 21, 2026

(54) SEMICONDUCTOR PACKAGE

(71) Applicant: Samsung Electronics Co., Ltd., Suwon-si (KR)

(72) Inventors: Sangho SHIN, Suwon-si (KR); Jihong PARK, Suwon-si (KR); Haejung YU, Suwon-si (KR); Yanggyoo JUNG, Suwon-si (KR)

(73) Assignee: Samsung Electronics Co., Ltd., Suwon-si (KR)

(21) Appl. No.: 19/193,403

(22) Filed: Apr. 29, 2025

(30) Foreign Application Priority Data
Nov. 18, 2024 (KR) 10-2024-0163929

(51) Int. Cl. H01L 23/544; H01L 23/00; H01L 25/18; H10B 80/00; H10D 80/30

(52) U.S. Cl. CPC H10W 46/00; H10W 90/00; H10B 80/00; H10D 80/30; H10W 46/301; H10W 72/9445; H10W 74/15; H10W 80/312; H10W 80/327; H10W 90/20; H10W 90/297; H10W 90/722; H10W 90/732; H10W 90/792

(57) ABSTRACT

Provided is the alignment pattern groups including a first alignment pattern group and a second alignment pattern group adjacent to a first vertex and a second vertex opposing each other in a diagonal direction among the vertexes, respectively, the first alignment pattern group including a first reference pattern, a first row pattern spaced apart from the first reference pattern in a first forward direction, and a first column pattern spaced apart from the first reference pattern in a second forward direction perpendicular to the first forward direction, and the second alignment pattern group including a second reference pattern, a second row pattern spaced apart from the second reference pattern in the first reverse direction opposite to the first forward direction, and a second column pattern spaced apart from the second reference pattern in the second reverse direction opposite to the second forward direction.

### CROSS-REFERENCE TO RELATED APPLICATION(S)

This application claims benefit of priority to Korean Patent Application No. 10-2024-0163929 filed on Nov. 18, 2024 in the Korean Intellectual Property Office, the disclosure of which is incorporated herein by reference in its entirety.

### BACKGROUND

Example embodiments of the present disclosure relate to semiconductor packages.

By disposing semiconductor chips on a large-area base substrate, a plurality of semiconductor packages may be manufactured, and productivity of a semiconductor packaging process may be improved. As a process of attaching a semiconductor chip is repeated, misalignment may occur and yield may decrease. Also, edge chipping and slant cutting of a semiconductor chip having a reduced size and thickness may reduce misalignment determination accuracy.

### SUMMARY

Example embodiments of the present disclosure is to provide semiconductor packages having improved alignment accuracy.

According to some example embodiments of the present disclosure, a semiconductor package includes at least one semiconductor chip including connection pads, and edges defining a front surface, the connection pads on the front surface; a base chip including upper pads electrically connected to the connection pads, an overlap region, the at least one semiconductor chip and the upper pads being on the overlap region, and alignment pattern groups including reference patterns in the overlap region and row patterns and column patterns outside the overlap region, wherein the overlap region includes outlines corresponding to the edges of at least one semiconductor chip, and vertexes at which the outlines intersect, the alignment pattern groups including a first alignment pattern group and a second alignment pattern group adjacent to a first vertex and a second vertex opposing each other in a diagonal direction among the vertexes, respectively, the first alignment pattern group including a first reference pattern, a first row pattern spaced apart from the first reference pattern in a first forward direction, and a first column pattern spaced apart from the first reference pattern in a second forward direction perpendicular to the first forward direction, and the second alignment pattern group including a second reference pattern, a second row pattern spaced apart from the second reference pattern in the first reverse direction opposite to the first forward direction, and a second column pattern spaced apart from the second reference pattern in the second reverse direction opposite to the second forward direction.

According to some example embodiments of the present disclosure, a semiconductor package includes at least one semiconductor chip including connection pads; a base chip including an overlap region, the at least one semiconductor chip being on the overlap region, upper pads electrically connected to the connection pads, lower pads electrically connected to the upper pads, alignment pattern groups including reference patterns in the overlap region and peripheral patterns outside the overlap region; a mold layer covering the at least one semiconductor chip on the base chip; and external connection bumps below the base chip and electrically connected to the lower pads, the alignment pattern groups including at least one pair of alignment pattern groups symmetrical to a point of the base chip on a plane.

According to some example embodiments of the present disclosure, a semiconductor package includes at least one semiconductor chip; and a base chip including an overlap region, the at least one semiconductor chip being on the overlap region disposed, and alignment pattern groups including reference patterns in the overlap region, and peripheral patterns outside the overlap region, the overlap region including a first vertex and a second vertex opposing each other in a diagonal direction, the alignment pattern groups including a first alignment pattern group at the first vertex, and a second alignment pattern group disposed at the second vertex, the first alignment pattern group including at least one first reference pattern, and first peripheral patterns, the second alignment pattern group including at least one second reference pattern, and second peripheral patterns, the first peripheral patterns spaced apart from the at least one first reference pattern in a first forward direction and a second forward direction perpendicular to each other, and the second peripheral patterns spaced apart from the at least one second reference pattern in a first reverse direction and a second reverse direction perpendicular to each other.

According to some example embodiments of the present disclosure, a method of manufacturing a semiconductor package includes preparing a base wafer including die attachment regions, and a pair of alignment pattern groups in a diagonal direction in the die attachment regions, respectively, the pair of alignment pattern groups including reference patterns and peripheral patterns; attaching a semiconductor chip to a position overlapping the reference patterns of each of the die attachment regions; and determining a defective unit in which the semiconductor chip is misaligned in the die attachment regions by sensing whether the peripheral patterns of each of the die attachment regions overlap the semiconductor chip, the defective unit being a region in which at least a portion of the semiconductor chip overlaps the peripheral patterns, the pair of alignment pattern groups including a first alignment pattern group and a second alignment pattern group, the first alignment pattern group including at least one first reference pattern and first peripheral patterns, the second alignment pattern group including at least one second reference pattern and second peripheral patterns, the first peripheral patterns spaced apart from the at least one first reference pattern in a first forward direction and a second forward direction perpendicular to each other, and the second peripheral patterns spaced apart from the at least one second reference pattern in a first reverse direction and a second reverse direction perpendicular to each other.

According to some example embodiments of the present disclosure, a method of manufacturing a semiconductor package includes attaching semiconductor chips to a base wafer, the base wafer including scribe lanes, die attachment regions defined by the scribe lanes, upper pads in the die attachment regions, and alignment pattern groups in each of the die attachment regions, sensing a position of each of the semiconductor chips based on the alignment pattern groups, determining whether the semiconductor chips are defective based on the respective positions of each of the semiconductor chips in relation to the alignment pattern groups, and stopping placement of further semiconductor chips in a die attachment region including at least one semiconductor chip determined to be defective.

According to some example embodiments of the present disclosure, the method of manufacturing the semiconductor package, wherein the alignment pattern groups each including reference patterns and peripheral patterns.

According to some example embodiments of the present disclosure, a semiconductor chip including upper pads, an overlap region, the upper pads being on the overlap region, and alignment pattern groups including reference patterns in the overlap region and row patterns and column patterns outside the overlap region, the overlap region defined by outlines, and vertexes at which the outlines intersect, the alignment pattern groups including a first alignment pattern group and a second alignment pattern group adjacent to a first vertex and a second vertex opposing each other in a diagonal direction among the vertexes, respectively, the first alignment pattern group including a first reference pattern, a first row pattern spaced apart from the first reference pattern in a first forward direction, and a first column pattern spaced apart from the first reference pattern in a second forward direction perpendicular to the first forward direction, and the second alignment pattern group including a second reference pattern, a second row pattern spaced apart from the second reference pattern in the first reverse direction opposite to the first forward direction, and a second column pattern spaced apart from the second reference pattern in the second reverse direction opposite to the second forward direction.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a perspective diagram illustrating a semiconductor package according to some example embodiments of the present disclosure;

FIGS. 1B and 1C are plan diagrams illustrating a semiconductor package according to some example embodiments of the present disclosure;

FIGS. 2A and 2B are plan diagrams illustrating a semiconductor package according to some example embodiments of the present disclosure;

FIGS. 3A and 3B are plan diagrams illustrating a semiconductor package according to some example embodiments of the present disclosure;

FIG. 4 is a plan diagram illustrating a semiconductor package according to some example embodiments of the present disclosure;

FIG. 5 is a plan diagram illustrating a semiconductor package according to some example embodiments of the present disclosure;

FIG. 6 is a plan diagram illustrating a semiconductor package according to some example embodiments of the present disclosure;

FIG. 7 is a plan diagram illustrating a semiconductor package according to some example embodiments of the present disclosure;

FIG. 8 is a plan diagram illustrating a semiconductor package according to some example embodiments of the present disclosure;

FIG. 9 is a side cross-sectional diagram illustrating a semiconductor package according to some example embodiments of the present disclosure;

FIG. 10 is a side cross-sectional diagram illustrating a semiconductor package according to some example embodiments of the present disclosure;

FIG. 11 is a side cross-sectional diagram illustrating a semiconductor package according to some example embodiments of the present disclosure;

FIG. 12A is a perspective diagram illustrating a semiconductor package according to some example embodiments of the present disclosure;

FIG. 12B is a plan diagram illustrating a semiconductor package according to some example embodiments of the present disclosure;

FIG. 13A is a side cross-sectional diagram illustrating a semiconductor package according to some example embodiments of the present disclosure;

FIG. 13B is an enlarged diagram illustrating region ‘A’ in FIG. 13A;

FIG. 14A is a side cross-sectional diagram illustrating a semiconductor package according to some example embodiments of the present disclosure;

FIG. 14B is an enlarged diagram illustrating region ‘B’ in FIG. 14A;

FIG. 15 is a side cross-sectional diagram illustrating a semiconductor package according to some example embodiments of the present disclosure;

FIG. 16 is a side cross-sectional diagram illustrating a semiconductor package according to some example embodiments of the present disclosure; and

FIGS. 17, 18A to 18D, and 19 are diagrams illustrating a method of manufacturing a semiconductor package according to some example embodiments of the present disclosure.

### DETAILED DESCRIPTION

Hereinafter, example embodiments of the present disclosure will be described as follows with reference to the accompanying drawings.

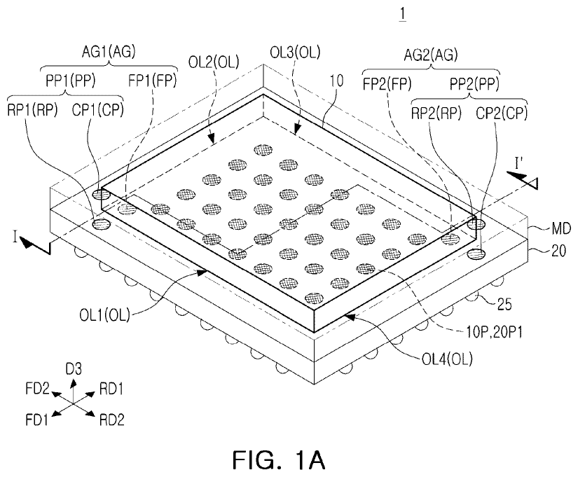

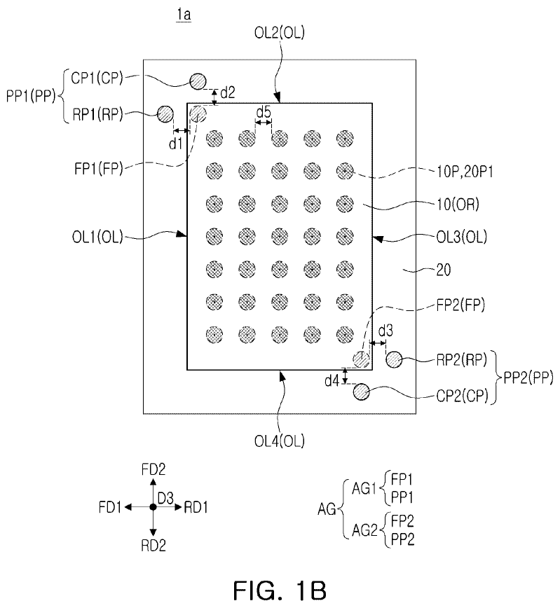

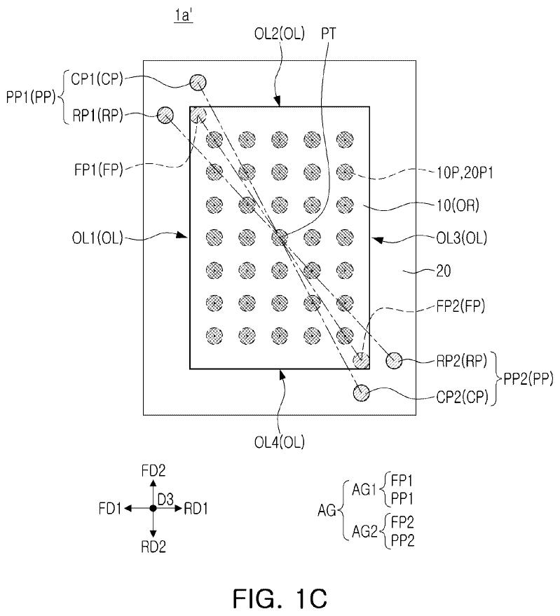

FIG. 1A is a perspective diagram illustrating a semiconductor package according to some example embodiments. FIGS. 1B and 1C are plan diagrams illustrating a semiconductor package according to some example embodiments.

Referring to FIGS. 1A, 1B, and 1C, a semiconductor package 1 in some example embodiments may include at least one semiconductor chip 10, and a base chip 20. In some example embodiments, the semiconductor package 1 may further include a mold layer MD. The mold layer MD may include, for example, an epoxy mold compound (EMC), but the material of the mold layer MD is not limited to any particular example.

The semiconductor chip 10 may include a semiconductor wafer and an integrated circuit (IC) formed of a semiconductor element such as silicon, germanium, or a compound semiconductor such as silicon carbide (SiC), gallium arsenide (GaAs), indium arsenide (InAs), and indium phosphide (InP). The semiconductor chip 10 may be a bare semiconductor chip without a separate bump or wiring layer formed thereon. In some example embodiments, the semiconductor chip 20 may be configured as a packaged type semiconductor chip having connection bumps formed on connection pads 10P.

The semiconductor chip 10 may include a logic chip such as a central processor (CPU), a graphic processor (GPU), a field programmable gate array (FPGA), an application processor AP, a digital signal processor, an encryption processor, a microprocessor, a microcontroller, an analog-to-digital converter, an application-specific IC (ASIC), or a memory chip including volatile memory such as a dynamic RAM (DRAM), static RAM (SRAM), and nonvolatile memory such as phase change RAM (PRAM), magnetic RAM (MRAM), resistive RAM (RRAM), and flash memory.

The semiconductor chip 10 may include connection pads 10P for connecting to an integrated circuit. The connection pads 10P may include at least one metal from among copper (Cu), aluminum (Al), nickel (Ni), silver (AG), gold (Au), platinum (PT), tin (Sn), lead (Pb), titanium (Ti), chromium (Cr), palladium (Pd), indium (In), and zinc (Zn), or an alloy including two or more metals.

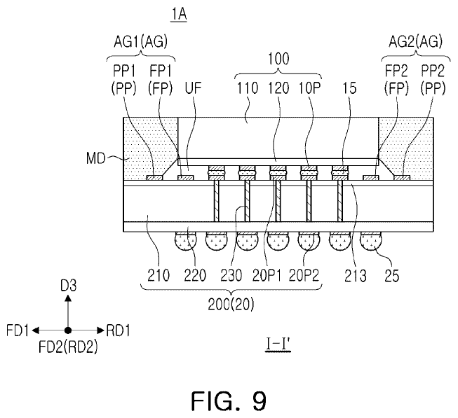

The base chip 20 may be an IC chip including a logic chip and a memory chip, such as the semiconductor chip 10, or a substrate configured to redistribute the connection pads 10P of the semiconductor chip 10. For example, the base chip 20 may be configured as a substrate for a semiconductor package including a printed circuit board (PCB), a ceramic substrate, a glass substrate, a tape wiring substrate, or the like. The base chip 20 may include upper pads 20P1 electrically connected to the connection pads 10P of the semiconductor chip 10. Also, the base chip 20 may further include lower pads on which external connection bumps 25 are disposed (see FIGS. 9-11). The external connection bumps 25 may include, for example, tin (Sn), indium (In), bismuth (Bi), antimony (Sb), copper (Cu), silver AG, zinc (Zn), lead (Pb) and/or alloys thereof. In some example embodiments, the external connection bumps 25 may have a combination of metal pillars and solder balls.

According to some example embodiments, the semiconductor package 1 may include at least one pair of alignment pattern groups AG for identifying the alignment status of the base chip 20 and the semiconductor chip 10. The alignment pattern groups AG may be disposed around an alignment position of the semiconductor chip 10 so as to oppose in a diagonal direction. Since the alignment pattern groups AG in some example embodiments include reference patterns FP and peripheral patterns PP, the misalignment determination accuracy of the semiconductor chip 10 may be improved regardless of edge chipping and slant cutting of the semiconductor chip 10.

The base chip 20 may include an overlap region OR in which the semiconductor chip 10 is disposed, and alignment pattern groups AG disposed at vertexes of the overlap region OR opposing each other in the diagonal direction. The overlap region OR may be understood as a region on the base chip 20 overlapping the semiconductor chip 10 in a vertical direction D3. Also, the overlap region OR may be a region in which upper pads 20P1 of the base chip 20 are disposed. The overlap region OR may be defined by edges of the front surface of the semiconductor chip 10 in which the connection pads 10P are disposed. The overlap region OR may include outlines OL corresponding to the edges of the semiconductor chip 10, and vertexes at which the outlines OL intersect.

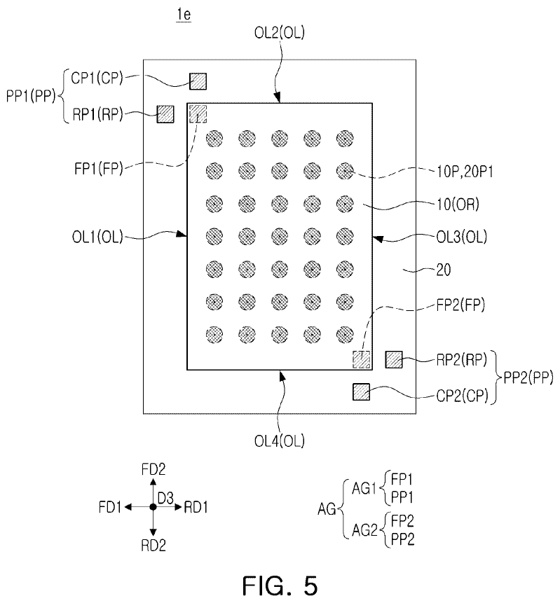

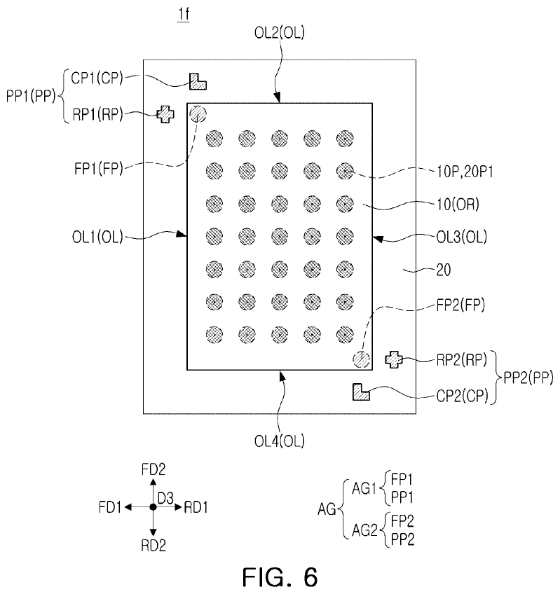

The alignment pattern groups AG may include reference patterns FP in the overlap region OR, and peripheral patterns PP outside the overlap region OR. In some example embodiments, the reference patterns FP may partially overlap the overlap region OR. The reference patterns FP and the peripheral patterns PP may have the same planar shape as that of the upper pads 20P1. In some example embodiments, the reference patterns FP and the peripheral patterns PP may have planar shapes different from those of the upper pads 20P1 (e.g., some example embodiments in FIGS. 5 and 6). The peripheral patterns PP may include row patterns RP spaced apart from the reference patterns FP in a first direction FD1 and RD1 and column patterns CP spaced apart from the reference patterns FP in a second direction FD2 and RD2.

The alignment pattern groups AG may include a first alignment pattern group AG1 and a second alignment pattern group AG2 disposed at the first vertex and the second vertex of the overlap region OR, respectively, opposing each other in a diagonal direction. In some example embodiments, the alignment pattern groups AG may include two pairs of alignment pattern groups AG disposed at the vertexes of the overlap region OR, respectively.

The first alignment pattern group AG1 may include at least one first reference pattern FP1, and first peripheral patterns PP1. The first peripheral patterns PP1 may be spaced apart from at least one first reference pattern FP1 in the first forward direction FD1 and the second forward direction FD2, perpendicular to each other. The first peripheral patterns PP1 may include a first row pattern RP1 spaced apart from a first reference pattern FP1 in the first forward direction FD1, and a first column pattern CP1 spaced apart from a first reference pattern FP1 in the second forward direction FD2 perpendicular to the first forward direction FD1.

The second alignment pattern group AG2 may include at least one second reference pattern FP2, and second peripheral patterns PP2. The second peripheral patterns PP2 may be spaced apart from at least one second reference pattern PP2 in a first reverse direction RD1 and a second reverse direction RD2 perpendicular to each other. The second peripheral patterns PP2 may include a second row pattern RP2 spaced apart from a second reference pattern FP2 in the first reverse direction RD1 opposite to the first forward direction FD1, and a second column pattern CP2 spaced apart from a second reference pattern FP2 in the second reverse direction RD2 opposite to the second forward direction FD2.

Also, the first alignment pattern group AG1 and the second alignment pattern group AG2 may be disposed symmetrically to a point PT on the base chip 20 on a plane. For example, the first reference pattern FP1 and the second reference pattern FP2 may be positioned symmetrically to the point PT of the base chip 20, and the first peripheral pattern PP1 and the second peripheral pattern PP2 may be positioned symmetrically to the point PT of the base chip 20 (see FIG. 1C).

According to some example embodiments, distances d1, d2, d3, and d4 between the peripheral patterns PP and the reference patterns FP may be substantially the same. Also, the distances d1, d2, d3, and d4 between the peripheral patterns PP and the reference patterns FP may be the same as or smaller than a minimum distance d5 between upper pads 20P1. In the instant specification, the configuration of being ‘substantially the same’ and ‘the same’ may include a tolerance or being substantially the same, and may indicate that the distances are designed to the same or substantially the same size. The distances d1, d2 between at least one first reference pattern FP1 and first peripheral patterns PP1 in the first forward direction FD1 and the second forward direction FD2 may be the same as the distances d3, d4 between at least one second reference pattern FP2 and second peripheral patterns PP2 in the first reverse direction RD1 and the second reverse direction RD2. Accordingly, as long as the overlap region OR overlaps the reference patterns FP at least partially while not overlapping the peripheral patterns PP, the connection pads 10P and the upper pads 20P1 may satisfy the required alignment margin.

The first distance d1 between the first reference pattern FP1 and the first row pattern RP1, the second distance d2 between the first reference pattern FP1 and the first column pattern CP1, the third distance d3 between the second reference pattern FP2 and the second row pattern RP2, and the fourth distance d4 between the second reference pattern FP2 and the second column pattern CP2 may be the same. The first distance d1, the second distance d2, the third distance d3, and the fourth distance d4 may be equal to or smaller than the minimum distance d5 between the upper pads 20P1. The minimum distance d5 between the upper pads 20P1 may be about or exactly 50 μm or less (e.g., 0 μm), for example, about or exactly 10 μm to about or exactly 50 μm, about or exactly 10 μm to about or exactly 40 μm, about or exactly 10 μm to about or exactly 30 μm, or the like. The first distance d1, the second distance d2, the third distance d3, and the fourth distance d4 may be about or exactly 50% or more of the minimum distance d5 between the upper pads 20P1 (e.g., about or exactly 50% to about or exactly 200% of the minimum distance d5). In some example embodiments, for fine alignment of the connection pads 10P and the upper pads 20P1, the first distance d1, the second distance d2, the third distance d3, and the fourth distance d4 may be about or exactly 50% or less (e.g., 0%) of the minimum distance d5 between the upper pads 20P1.

According to some example embodiments, alignment accuracy of the semiconductor chip 10 may be determined by visually sensing the arrangement relationship between the outlines OL of the overlap region OR and the peripheral patterns PP. When the semiconductor chip 10 is aligned in the designed alignment position, spacings between the outlines OL of the overlap region OR and the peripheral patterns PP may be substantially the same. The outlines OL of the overlap region OR may include the first outline OL1 adjacent to the first row pattern RP1, the second outline OL2 adjacent to the first column pattern CP1, the third outline OL3 adjacent to the second row pattern RP2, and the fourth outline OL4 adjacent to the second column pattern CP2. The spacing between the first row pattern RP1 and the first outline OL1, the spacing between the first column pattern CP1 and the second outline OL2, the spacing between the second row pattern RP2 and the third outline OL3, and the spacing between the second column pattern CP2 and the fourth outline OL4 may be substantially the same.

Also, in some example embodiments, when the semiconductor chip 10 is aligned in the designed alignment position, the outlines OL of the overlap region OR may be spaced apart from the reference patterns FP. As illustrated in FIG. 1B, the first outline OL1 and the second outline OL2 may have a predetermined (or, alternatively, desired or determined) gap with the first reference pattern FP1, and the third outline OL3 and the fourth outline OL4 may have a predetermined (or, alternatively, desired or determined) gap with the second reference pattern FP2. The gap between the outlines OL of the overlap region OR and the reference patterns FP may be an alignment margin considering a process error. In some example embodiments, the outlines OL of the overlap region OR and the reference patterns FP may be in contact with each other. As illustrated in FIG. 1C, in the semiconductor package 1a′ of some example embodiments, the first reference pattern FP1 may be in contact with the first outline OL1 and the second outline OL2, and the second reference pattern FP2 may be in contact with the third outline OL3 and the fourth outline OL4.

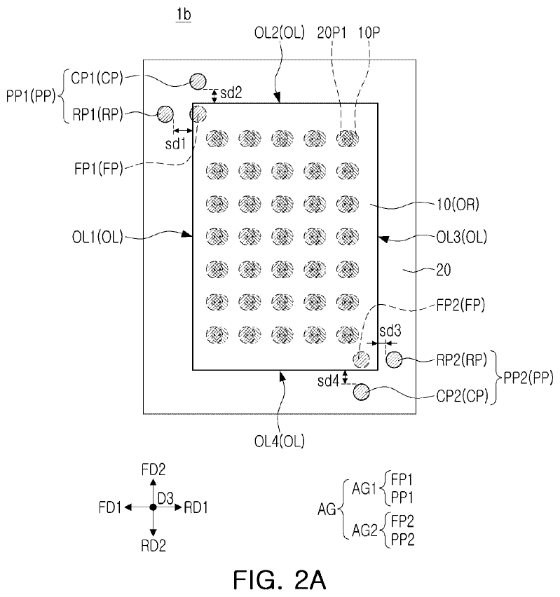

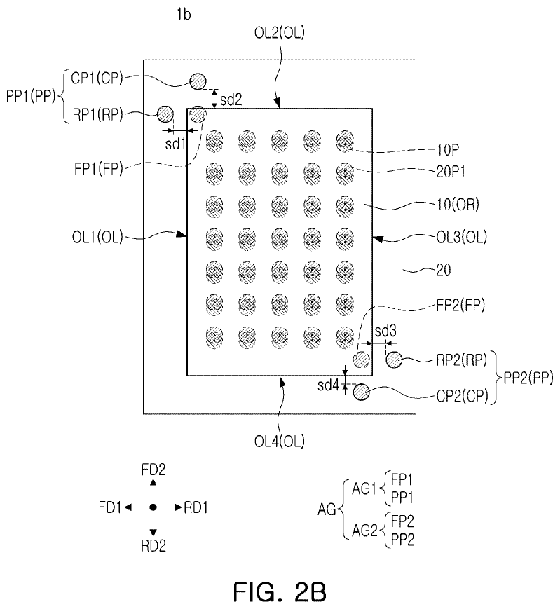

Hereinafter, example embodiments satisfying the ‘alignment margin’ defined by the alignment pattern groups AG will be described with reference to FIGS. 2A to 4. According to some example embodiments, by configuring a distance between the row pattern RP and the column pattern CP with respect to the reference pattern FP, an area in which the connection pads 10P and the upper pads 20P1 overlap in the alignment margin may be controlled. That is, when the alignment margin by the alignment pattern groups AG is satisfied, the connection pads 10P and the upper pads 20P1 may overlap each other by about or exactly 50% or more (e.g., up to a total overlap) of the planar area, which may be, however, merely due to the distance configuration described above and is not a criterion for the alignment margin. In some example embodiments, the alignment margin by the alignment pattern groups AG may be configured such that the connection pads 10P and the upper pads 20P1 overlap each other by less than about or exactly 50% of the planar area (e.g., an overlap between about or exactly 0% and about or exactly 50%).

FIGS. 2A and 2B are plan diagrams illustrating a semiconductor package 1b according to some example embodiments.

Referring to FIGS. 2A and 2B, a semiconductor package 1b in some example embodiments may be configured the same as or similar to the example described with reference to FIGS. 1A to 1C, other than the configuration the positions of the overlap region OR are changed. The semiconductor chip 10 may be shifted in the first direction FD1 and RD1 or in the second direction FD2 and RD2 from the designed alignment position. Centers of the connection pads 10P of the semiconductor chip 10 and centers of the upper pads 20P1 of the base chip 20 may be spaced apart from each other in the vertical direction or the horizontal direction. The first spacing sd1 between the first row pattern RP1 and the first outline OL1, and the second spacing sd2 between the first column pattern CP1 and the second outline OL2 may be different from each other, and the third spacing sd3 between the second row pattern RP2 and the third outline OL3, and the fourth spacing sd4 between the second column pattern CP2 and the fourth outline OL4 may be different from each other.

As illustrated in FIG. 2A, the center of the connection pads 10P may be spaced apart from the center of the upper pads 20P1 in the first reverse direction RD1. A portion of the first reference pattern FP1 may be positioned externally of the overlap region OR. The first spacing sd1 between the first row pattern RP1 and the first outline OL1 may be larger than the second spacing sd2 between the first column pattern CP1 and the second outline OL2. The third spacing sd3 between the second row pattern RP2 and the third outline OL3 may be smaller than the fourth spacing sd4 between the second column pattern CP2 and the fourth outline OL4.

As illustrated in FIG. 2B, the center of the connection pads 10P may be spaced apart from the center of the upper pads 20P1 in the second reverse direction RD2. A portion of the second reference pattern FP2 may be positioned externally of the overlap region OR. The first spacing sd1 between the first row pattern RP1 and the first outline OL1 may be smaller than the second spacing sd2 between the first column pattern CP1 and the second outline OL2. The third spacing sd3 between the second row pattern RP2 and the third outline OL3 may be smaller than the fourth spacing sd4 between the second column pattern CP2 and the fourth outline OL4.

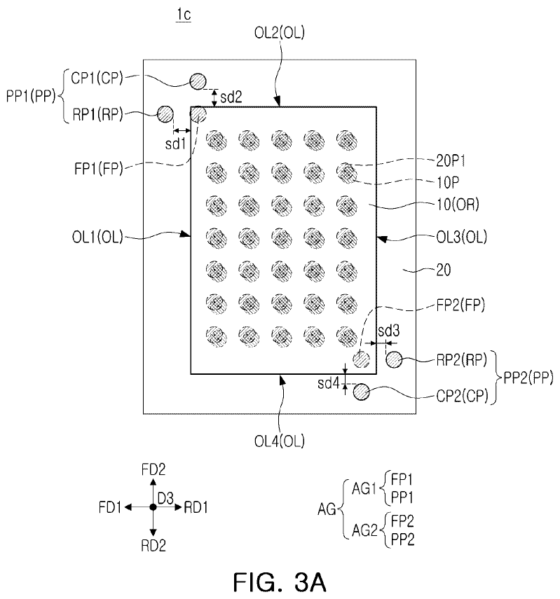

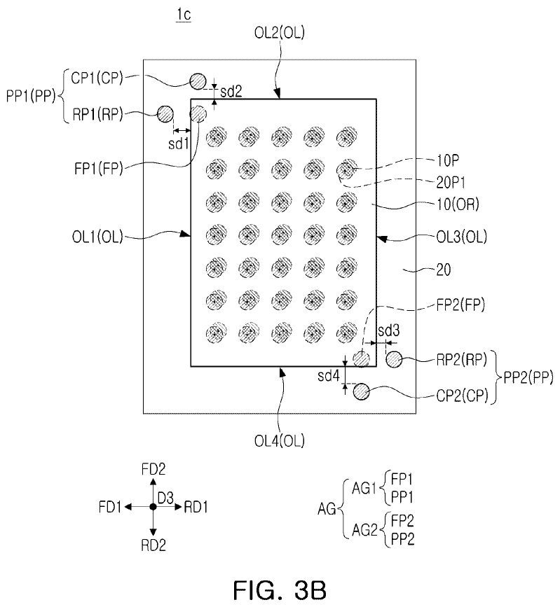

FIGS. 3A and 3B are plan diagrams illustrating a semiconductor package 1c according to some example embodiments.

Referring to FIGS. 3A and 3B, a semiconductor package 1c in some example embodiments may be configured the same as or similar to the example described with reference to FIGS. 1A to 2B, other than the configuration in which the position of the overlap region OR is changed. The semiconductor chip 10 may be shifted in the first direction FD1 and RD1 and in the second direction FD2 and RD2 from the designed alignment position. The center of the connection pads 10P of the semiconductor chip 10 and the center of the upper pads 20P1 of the base chip 20 may be spaced apart from each other in the diagonal direction.

As illustrated in FIG. 3A, the center of the connection pads 10P may be spaced apart from the center of the upper pads 20P1 in the first reverse direction RD1 and in the second reverse direction RD2. A portion of the first reference pattern FP1 may be positioned externally of the overlap region OR. The first spacing sd1 between the first row pattern RP1 and the first outline OL1, and the second spacing sd2 between the first column pattern CP1 and the second outline OL2 may be the same, and the third spacing sd3 between the second row pattern RP2 and the third outline OL3, and the fourth spacing sd4 between the second column pattern CP2 and the fourth outline OL4 may be the same.

As illustrated in FIG. 3B, the center of the connection pads 10P may be spaced apart from the center of the upper pads 20P1 in the second forward direction FD2 and the first reverse direction RD1. A portion of the first reference pattern FP1 and a portion of the second reference pattern FP2 may be positioned externally of the overlap region OR, respectively. The first spacing sd1 between the first row pattern RP1 and the first outline OL1 may be larger than the second spacing sd2 between the first column pattern CP1 and the second outline OL2. The third spacing sd3 between the second row pattern RP2 and the third outline OL3 may be smaller than the fourth spacing sd4 between the second column pattern CP2 and the fourth outline OL4.

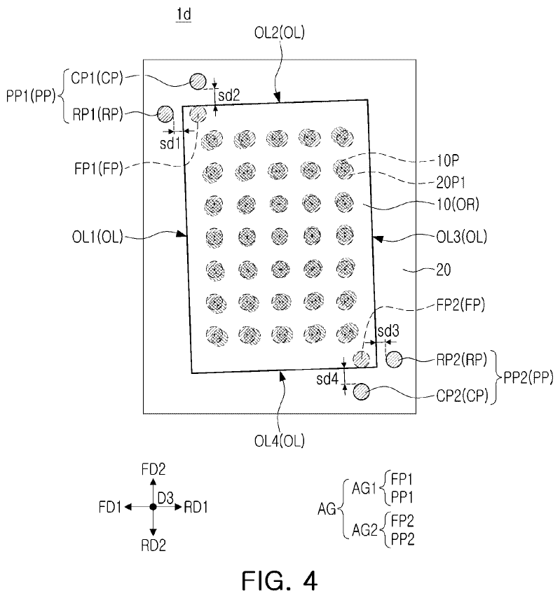

FIG. 4 is a plan diagram illustrating a semiconductor package 1d according to some example embodiments.

Referring to FIG. 4, the semiconductor package 1d in some example embodiments may be configured the same as or similar to the example described with reference to FIGS. 1A to 3b, other than the configuration in which the position of the overlap region OR is changed. The semiconductor chip 10 may be rotated in a clockwise or counterclockwise direction relative to the designed alignment position. Each of the outlines OL of the overlap region OR may have a slope with respect to a side surface of the corresponding base chip 20. The centers of the connection pads 10P of the semiconductor chip 10 and the centers of the upper pads 20P1 of the base chip 20 may be spaced apart from each other in the clockwise or counterclockwise direction.

In some example embodiments, by being positioned farther from the rotational center of the semiconductor chip 10, the centers of the connection pads 10P may be shifted more greatly relative to the centers of the upper pads 20P1. A portion of the first reference pattern FP1 and a portion of the second reference pattern FP2 may be positioned externally of the overlap region OR. A first spacing sd1 between the first row pattern RP1 and the first outline OL1 may be smaller than a second spacing sd2 between the first column pattern CP1 and the second outline OL2. A third spacing sd3 between the second row pattern RP2 and the third outline OL3 may be smaller than a fourth spacing sd4 between the second column pattern CP2 and the fourth outline OL4. Each of the first outline OL1, the second outline OL2, the third outline OL3, and the fourth outline OL4 may have a slope with respect to the corresponding side surface of the base chip 20.

FIG. 5 is a plan diagram illustrating a semiconductor package 1e according to some example embodiments.

Referring to FIG. 5, a semiconductor package 1e in some example embodiments may be configured the same as or similar to the example described with reference to FIGS. 1A to 4, other than the configuration in which the planar shape of the alignment pattern groups AG is changed. The reference patterns FP and the peripheral patterns PP of the alignment pattern groups AG may have a planar shape different from a planar shape of the upper pads 20P1 of the base chip 20. The reference patterns FP and the peripheral patterns PP may have a planar shape of a circular shape or a polygonal shape. For example, the planar shape of the upper pads 20P1 may be a circular shape, and the planar shapes of the reference patterns FP and the peripheral patterns PP may be a quadrangular shape. Since the alignment pattern groups AG have a planar shape different from that of the upper pads 20P1, visibility of the alignment pattern groups AG may be improved.

FIG. 6 is a plan diagram illustrating a semiconductor package 1f according to some example embodiments.

Referring to FIG. 6, a semiconductor package 1f in some example embodiments may be configured the same as or similar to the example described with reference to FIGS. 1A to 5, other than the configuration in which the planar shapes of the alignment pattern groups AG are changed. The peripheral patterns PP of the alignment pattern groups AG may have a planar shape different from the planar shape of the reference patterns FP. For example, the planar shape of the reference patterns FP may be a circular shape, and the planar shape of the peripheral patterns PP may be a polygonal shape. Also, the row patterns RP and the column patterns CP may have different planar shapes. In some example embodiments, the row patterns RP may have the same planar shape, and the column patterns CP may have the same planar shape. For example, the planar shape of the reference patterns FP may be a circular shape, the planar shape of the row patterns RP may be a cross shape, and the planar shape of the column patterns CP may be a curved shape. By having a planar shape distinguishing the peripheral patterns PP exposed in the overlap region OR, visibility of the alignment pattern groups AG may be improved.

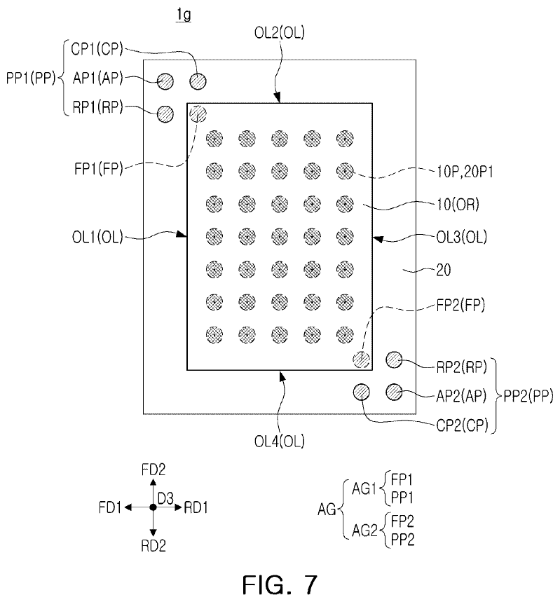

FIG. 7 is a plan diagram illustrating a semiconductor package 1g according to some example embodiments.

Referring to FIG. 7, a semiconductor package 1g in some example embodiments may be configured the same as or similar to the example described with reference to FIGS. 1A to 6, except for a configuration further including auxiliary patterns AP. Each of the alignment pattern groups AG may further include an auxiliary pattern AP disposed between adjacent row patterns RP and column patterns CP. The auxiliary pattern AP may be adjacent to the reference pattern FP in a diagonal direction. A first alignment pattern group AG1 may include a first auxiliary pattern AP1 between the first row pattern RP1 and the first column pattern CP1. The first auxiliary pattern AP1 may be adjacent to the first reference pattern FP1 in a direction toward the second alignment pattern group AG2. The second alignment pattern group AG2 may include a second auxiliary pattern AP2 between the second row pattern RP2 and the second column pattern CP2. The second auxiliary pattern AP2 may be adjacent to the second reference pattern FP2 in a direction toward the first alignment pattern group AG1. Auxiliary patterns AP may further enhance visibility of alignment pattern groups AG. In some example embodiments, auxiliary patterns AP may have different planar shapes than row patterns RP and column patterns CP.

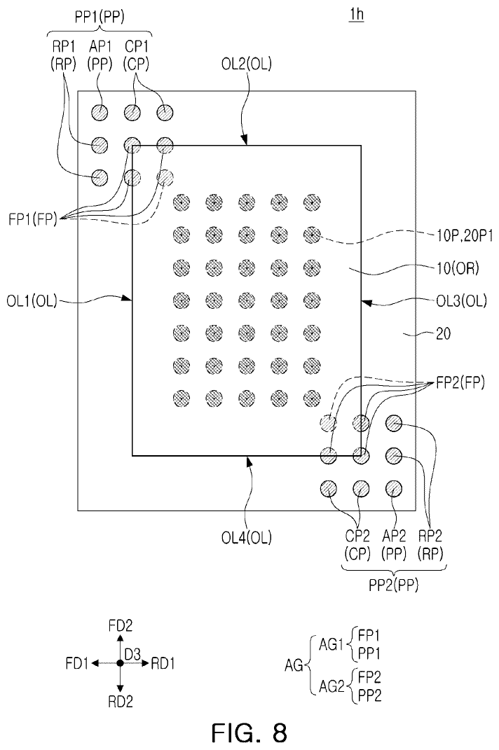

FIG. 8 is a plan diagram illustrating a semiconductor package 1h according to some example embodiments.

Referring to FIG. 8, a semiconductor package 1h in some example embodiments may be configured the same as or similar to the example described with reference to FIGS. 1A to 7, other than the configuration in which each of the alignment pattern groups AG includes a plurality of reference patterns FP. The plurality of reference patterns FP may be arranged in a matrix form at corners of the overlap region OR. At least a portion of the reference patterns FP of the plurality of reference patterns FP may be partially positioned externally of the overlap region OR. The first reference pattern FP1 of the first alignment pattern group AG1 may be provided as the plurality of first reference patterns FP1 disposed in an n x n matrix. The second reference pattern FP2 of the second alignment pattern group AG2 may be provided as the plurality of second reference patterns FP2 disposed in an m×m matrix. Here, n and m may be the same number. In some example embodiments, n and m may be different numbers. By disposing a plurality of the reference patterns FP and a plurality of the peripheral patterns PP, visibility of the alignment pattern groups AG and alignment accuracy of the semiconductor chip 10 may be improved.

The first alignment pattern group AG1 may include a plurality of first row patterns RP1 and a plurality of first column patterns CP1 spaced apart from the first reference patterns FP1 most adjacent to the outlines OL of the overlap region OR in the first forward direction FD1 and the second forward direction FD2. Also, the first alignment pattern group AG1 may further include a first auxiliary pattern AP1 between the first row pattern RP1 and the first column pattern CP1 most adjacent to each other.

The second alignment pattern group AG2 may include a plurality of second row patterns RP2 and a plurality of second column patterns CP2 spaced apart from the second reference patterns FP2 most adjacent to the outlines OL of the overlap region OR in the first reverse direction RD1 and the second reverse direction RD2. Also, the second alignment pattern group AG2 may further include a second auxiliary pattern AP2 between the second row pattern RP2 and the second column pattern CP2 most adjacent to each other.

FIG. 9 is a side cross-sectional diagram illustrating a semiconductor package 1A according to some example embodiments, taken along line I-I′.

Referring to FIG. 9, a semiconductor package 1A in some example embodiments may be configured the same as or similar to the example described with reference to FIGS. 1A to 8, other than configuration in which a first chip structure 100 and a first base chip 200 are included. The first chip structure 100 and the first base chip 200 may be understood as specific examples of the semiconductor chip 10 and the base chip 20 described above, respectively. The first chip structure 100 and the first base chip 200 may be configured as chiplets included in a multi-chip module (MCM). For example, the first base chip 200 may include a processor circuit, and the first chip structure 100 may include at least one of an input/output circuit, an analog circuit, a memory circuit, and a serial-to-parallel conversion circuit for a processor circuit.

The first chip structure 100 may include a substrate 110, a circuit layer 120, and connection pads 10P. The substrate 110 may be configured as a semiconductor wafer. The substrate 110 may include a semiconductor element, such as silicon, germanium, and/or a compound semiconductor, such as silicon carbide (SiC), gallium arsenide (GaAs), indium arsenide (InAs), and indium phosphide (InP). The substrate 110 may include a conductive region, such as a well doped with impurities. The circuit layer 120 may include an integrated circuit forming a logic chip or a memory chip. The circuit layer 120 may include individual devices electrically connected to the conductive region of the substrate 110, such as a FET such as planar FET or FinFET, memory devices such as flash memory, DRAM, SRAM, EEPROM, PRAM, MRAM, FeRAM, RRAM, logic devices such as AND, OR, NOT, various active devices, and/or passive devices such as system LSI, CIS, and MEMS. The connection pads 10P may be electrically connected to the integrated circuit of the circuit layer 120. The connection pads 10P may be connected to the upper pads 20P1 of the first base chip 200 through the connection bumps 15. The connection bumps 15 may be solder balls, but in some example embodiments, The connection bumps 15 may have a combination of metal pillars and solder balls.

The first base chip 200 may include a substrate 210, a circuit layer 220, and through-vias 230. The substrate 210 and the circuit layer 220 may be configured similarly to the substrate 110 and the circuit layer 120 of the first chip structure 100, such that overlapping descriptions will not be provided. The through-vias 230 may penetrate the substrate 210 in a vertical direction (D3 direction) and may provide an electrical path connecting the upper pads 20P1 to the lower pads 20P2. The through-vias 230 may include a conductive plug and a barrier film surrounding the conductive plug. The conductive plug may include a metal, for example, tungsten (W), titanium (Ti), aluminum (Al), and/or copper (Cu). The conductive plug may be formed by a plating process, a PVD process, and/or a CVD process. The barrier film may include an insulating barrier film and/or a conductive barrier film. The insulating barrier film may be formed of an oxide film, a nitride film, a carbide film, a polymer, or a combination thereof. The conductive barrier film may be disposed between the insulating barrier film and the conductive plug. The conductive barrier film may include a metal compound, for example, tungsten nitride (WN), titanium nitride (TiN), and/or tantalum nitride (TaN). The barrier film may be formed by a PVD process and/or a CVD process.

The first base chip 200 may include upper pads 20P1, lower pads 20P2 , and alignment pattern groups AG. The upper pads 20P1 may be electrically insulated from the substrate 210 by the buffer layer 213. The buffer layer 213 may include an insulating material such as a silicon oxide film, a silicon nitride film, and/or a silicon oxynitride film. The lower pads 20P2 may be connected to external connection bumps 25. The alignment pattern groups AG may include reference patterns FP and peripheral patterns PP. The reference patterns FP may overlap the first chip structure 100 in the vertical direction D3. The peripheral patterns PP may not overlap the first chip structure 100. The peripheral patterns PP may be spaced apart from the reference patterns FP in the horizontal direction. The first peripheral pattern PP1 may be spaced apart from the first reference pattern FP1 in the first forward direction FD1 and the second forward direction FD2. The second peripheral pattern PP2 may be spaced apart from the second reference pattern FP2 in the first reverse direction RD1 and the second reverse direction RD2.

In some example embodiments, the semiconductor package 1A may further include a mold layer MD and an underfill UF. The mold layer MD may include, for example, an EMC. The underfill UF may be disposed between the first chip structure 100 and the first base chip 200. The underfill UF may cover at least a portion of the reference patterns FP and the peripheral patterns PP. The underfill UF may include a thermosetting resin, such as an epoxy resin, and may be formed to seal the connection bumps 15 by a capillary underfill (CUF) method. In some example embodiments, the underfill UF may be formed integrally with the mold layer MD by a molded underfill (MUF) method.

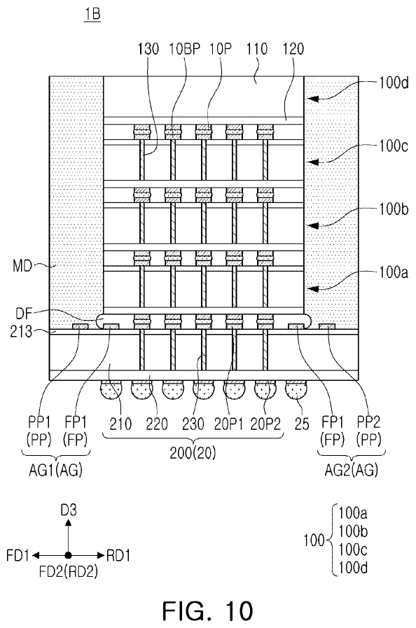

FIG. 10 is a side cross-sectional diagram illustrating a semiconductor package 1B according to some example embodiments.

Referring to FIG. 10, a semiconductor package 1B in some example embodiments may be configured the same as or similar to the example described with reference to FIGS. 1A to 9, other than configuration in which a plurality of first chip structures 100 stacked in a vertical direction D3 on a first base chip 20 are included, differently from the semiconductor package 1A in FIG. 9. The plurality of first chip structures 100 may be configured as a memory chip including volatile memory devices such as DRAM or SRAM, or nonvolatile memory devices such as PRAM, MRAM, FeRAM, or RRAM. The first base chip 200 may be a buffer chip or a control chip including a plurality of logic devices and/or memory devices. The first base chip 200 may transfer signals from the plurality of first chip structures 100 stacked thereon to an external entity, and may also transfer signals and power from an external entity to the plurality of first chip structures 100.

The plurality of first chip structures 100 may include an uppermost semiconductor chip 100d, and intermediate semiconductor chips 100a, 100b, and 100c between the uppermost semiconductor chip 100d and the first base chip 200. The plurality of first chip structures 100 may include components the same as or similar to those of the first chip structure 100 described in FIG. 9. However, the intermediate semiconductor chips 100a, 100b, and 100c, other than the uppermost semiconductor chip 100d, may further include through-vias 130 and backside pads 10BP. The through-vias 130 and the backside pads 10BP of the intermediate semiconductor chips 100a, 100b, and 100c may be configured similarly to the through-vias 230 and the upper pads 20P1 of the first base chip 200 described with reference to FIG. 9, respectively, such that overlapping descriptions will not be provided.

The plurality of first chip structures 100 may be electrically connected to each other through connection bumps 15. Adhesive films DF may be disposed between the plurality of first chip structures 100 and the first base chip 200. The adhesive films DF may be a non-conductive film (NCF), but some example embodiments thereof is not limited thereto, and the adhesive films DF may be formed by various sorts of insulating film for a thermocompression process, for example. The lowermost adhesive film DF may cover at least a portion of the reference patterns FP and the peripheral patterns PP.

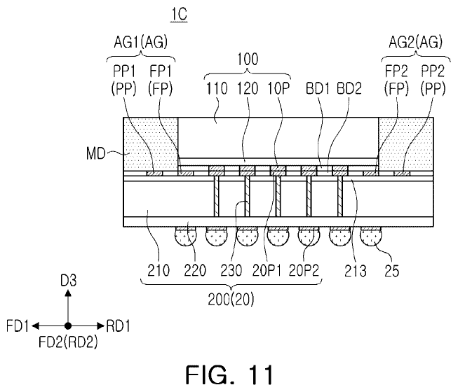

FIG. 11 is a side cross-sectional diagram illustrating a semiconductor package 1C according to some example embodiments.

Referring to FIG. 11, a semiconductor package 1C in some example embodiments may be configured the same as or similar to the example described with reference to FIGS. 1A to 10, other than the configuration the first chip structure 100 and the first base chip 200 are directly bonded and coupled to each other without a connecting member (e.g., solder ball, metal pillar, and/or the like) as compared to the semiconductor package 1A in FIG. 9. The first chip structure 100 and the first base chip 200 may be coupled to each other by metal-to-metal bonding and dielectric-to-dielectric bonding. The first chip structure 100 may include a first bonding layer BD1 surrounding connection pads 10P, and the first base chip 200 may include a second bonding layer BD2 surrounding upper pads 20P1. The first bonding layer BD1 and the second bonding layer BD2 may include materials which may be bonded and coupled to each other and may form dielectric bonding, for example, at least one of silicon oxide (SiO), silicon nitride (SiN), and silicon carbonitride (SiCN). The connection pads 10P and the upper pads 20P1 may include materials which may be bonded and coupled to each other and may form a metal bonding, for example, at least one of copper (Cu), nickel (Ni), gold (Au), silver AG, titanium (Ti), and tantalum (Ta).

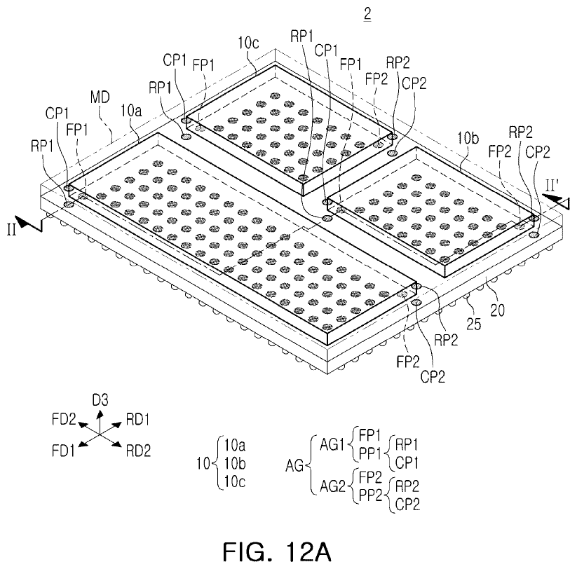

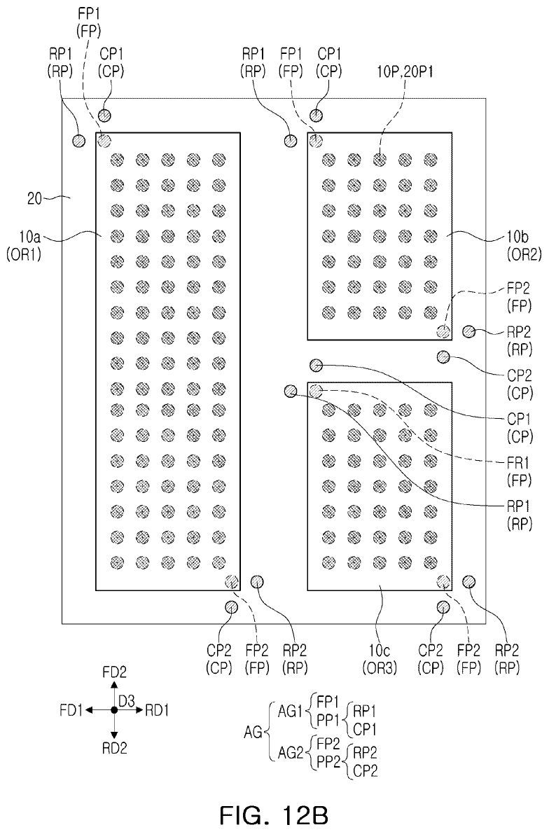

FIG. 12A is a perspective diagram illustrating a semiconductor package 2 according to some example embodiments. FIG. 12B is a plan diagram illustrating a semiconductor package according to some example embodiments.

Referring to FIGS. 12A and 12B, the semiconductor package 2 in some example embodiments may be configured the same as or similar to the example described with reference to FIGS. 1A to 11, other than the configuration in which a plurality of semiconductor chips 10a, 10b, and 10c disposed in a horizontal direction on a base chip 20 are included. Each of the plurality of semiconductor chips 10a, 10b, and 10c may define overlap regions OR on the base chip 20. The base chip 20 may include a first overlap region OR1, a second overlap region OR2, and a third overlap region OR3 corresponding to the first semiconductor chip 10a, the second semiconductor chip 10b, and the third semiconductor chip 10c, respectively. The alignment pattern groups AG may include a first alignment pattern group AG1 and a second alignment pattern group AG2 disposed in a diagonal direction at each corner of the first overlap region OR1, the second overlap region OR2, and the third overlap region OR3.

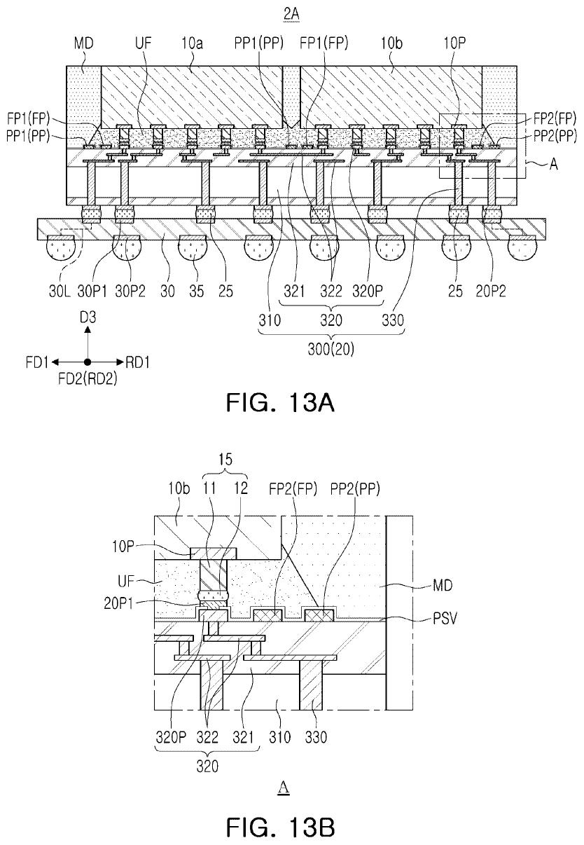

FIG. 13A is a side cross-sectional diagram illustrating a semiconductor package 2A according to some example embodiments. FIG. 13B is an enlarged diagram illustrating region ‘A’ in FIG. 13A. FIG. 13A illustrates a cross-section taken along line II-II′ in FIG. 12A.

Referring to FIGS. 13A and 13B, a semiconductor package 2A in some example embodiments may be configured the same as or similar to the example described with reference to FIGS. 1A to 12B, other than configuration in which a plurality of semiconductor chips 10a and 10b, a second base chip 300, and a package substrate 30 are included. The second base chip 300 may be understood as a specific example of the base chip 20 described above.

The package substrate 30 may be configured as a substrate for a semiconductor package including a printed circuit board (PCB), a ceramic substrate, a glass substrate, a tape wiring substrate, and/or the like. The package substrate 30 may include lower pads 30P2, upper pads 30P1, and redistribution circuit 30L. The lower pads 30P2 and the upper pads 30P1 may include at least one metal or an alloy of two or more metals selected from a group consisting of copper (Cu), aluminum (Al), nickel (Ni), silver AG, gold (Au), platinum PT, tin (Sn), lead (Pb), titanium (Ti), chromium (Cr), palladium (Pd), indium (In), and zinc (Zn). The lower pads 30P2 and the upper pads 30P1 may be electrically connected to each other through the redistribution circuit 30L. The redistribution circuit 30L may be formed of a material similar to that of the lower pads 30P2 and the upper pads 30P1. The upper pads 30P1 may be connected to first external connection bumps 25. The lower pads 30P2 may be connected to the second external connection bumps 35. The second external connection bumps 35 may be solder balls formed of, for example, tin (Sn) or an alloy including tin (Sn). In some example embodiments, an underfill surrounding the second external connection bumps 35 may be formed between the package substrate 30 and the second base chip 300.

The plurality of semiconductor chips 10a and 10b may include different types of semiconductor chips. For example, the first semiconductor chip 10a may include a logic chip such as a central processor (CPU), a graphics processor (GPU), a field programmable gate array (FPGA), a digital signal processor, an encryption processor, a microprocessor, a microcontroller, an analog-to-digital converter, an ASIC, and the second semiconductor chip 10b may include a memory chip such as a DRAM, an SRAM, a PRAM, a ReRAM, a FeRAM, an MRAM, a flash memory. The connection bumps 15 may include the pillar 11 on the connection pads 10P and the solder 12 on the pillar 11.

The second base chip 300 may be configured as an interposer substrate connecting the plurality of semiconductor chips 10a and 10b to the package substrate 30. The plurality of semiconductor chips 10a and 10b may be electrically connected to each other by means of the second base chip 300. In some example embodiments, the second base chip 300 may be used for converting or transferring an input electrical signal between the plurality of semiconductor chips 10a and 10b. The second base chip 300 may not include devices such as active devices or passive devices. The second base chip 300 may include a core substrate 310, an interconnection structure 320, and a through-electrode 330.

The core substrate 310 may be formed of, for example, one of a silicon, an organic, a plastic, and a glass substrate. When the core substrate 310 is configured as a silicon substrate, the second base chip 300 may be referred to as a silicon interposer. A buffer layer 313 surrounding a lower portion of the through-electrodes 330 may be formed between the core substrate 310 and the lower pads 20P2. An interconnection structure 320 may be disposed on the core substrate 310 and may include an interlayer insulating layer 321 and a single layer or multilayer wiring structure 322. When the interconnection structure 320 is formed as a multilayer wiring structure, wiring patterns on different layers may be connected to each other through contact vias. The wiring structure 322 may include wiring pads 320P in contact with the upper pads 20P1. The wiring pads 320P may be, for example, aluminum (Al) pads, but some example embodiments thereof is not limited thereto. The through-electrode 330 may penetrate the core substrate 310 and may electrically connect the lower pads 20P2 to the upper pads 20P1. When the core substrate 310 is configured as a silicon substrate, the through-electrode 330 may be referred to as a TSV.

The second base chip 300 may include alignment pattern groups AG corresponding to the plurality of semiconductor chips 10a and 10b, respectively. The alignment pattern groups AG may include reference patterns FP and peripheral patterns PP. The reference patterns FP may overlap the plurality of semiconductor chips 10a and 10b in the vertical direction D3. The peripheral patterns PP may not overlap the plurality of semiconductor chips 10a and 10b. The peripheral patterns PP may be spaced apart from the reference patterns FP in the horizontal direction. The first peripheral pattern PP1 may be spaced apart from the first reference pattern FP1 in a first forward direction FD1 and a second forward direction FD2. The second peripheral pattern PP2 may be spaced apart from the second reference pattern FP2 in a first reverse direction RD1 and a second reverse direction RD2.

In some example embodiments, the alignment pattern groups AG may be positioned at the same vertical level as the wiring pads 320P. The reference patterns FP and the peripheral patterns PP may overlap the wiring pads 320P in the horizontal direction. The wiring pads 320P, the reference patterns FP, and the peripheral patterns PP may be covered by the passivation layer PSV. The upper pads 20P1 may penetrate the passivation layer PSV and may be connected to the wiring pads 320P. The passivation layer PSV may cover the entire upper surface of the reference patterns FP and the peripheral patterns PP. The passivation layer PSV may include a dielectric material such as silicon nitride (SiN). The passivation layer PSV may be formed as a thin film such that the reference patterns FP and the peripheral patterns PP may be identified.

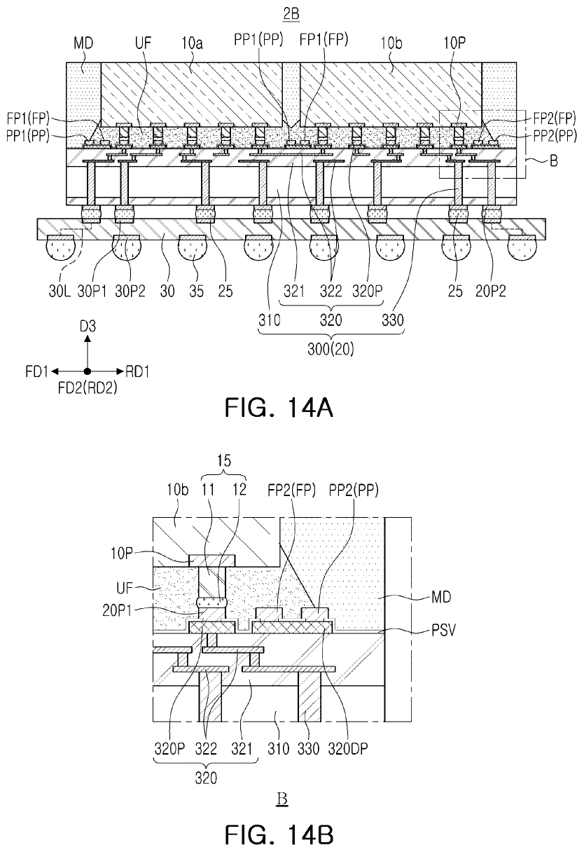

FIG. 14A is a side cross-sectional diagram illustrating a semiconductor package according to some example embodiments. FIG. 14B is an enlarged diagram illustrating region ‘B’ in FIG. 14A.

Referring to FIGS. 14A and 14B, a semiconductor package 2B in some example embodiments may be configured the same as or similar to the example described with reference to FIGS. 1A to 13B, other than the configuration in which a vertical level of alignment pattern groups AG is changed, as compared to the semiconductor package 2A in FIGS. 13A and 13B. In some example embodiments, the interconnection structure 320 may further include at least one dummy pad 320DP. The dummy pad 320DP may overlap the wiring pads 320P in the horizontal direction. The passivation layer PSV may extend conformally along a surface of the dummy pad 320DP. The alignment pattern groups AG may be positioned at the same vertical level as the upper pads 20P1. The reference patterns FP and the peripheral patterns PP may overlap the upper pads 20P1 in the horizontal direction. The reference patterns FP and the peripheral patterns PP may penetrate the passivation layer PSV and may be connected to the dummy pads 320DP.

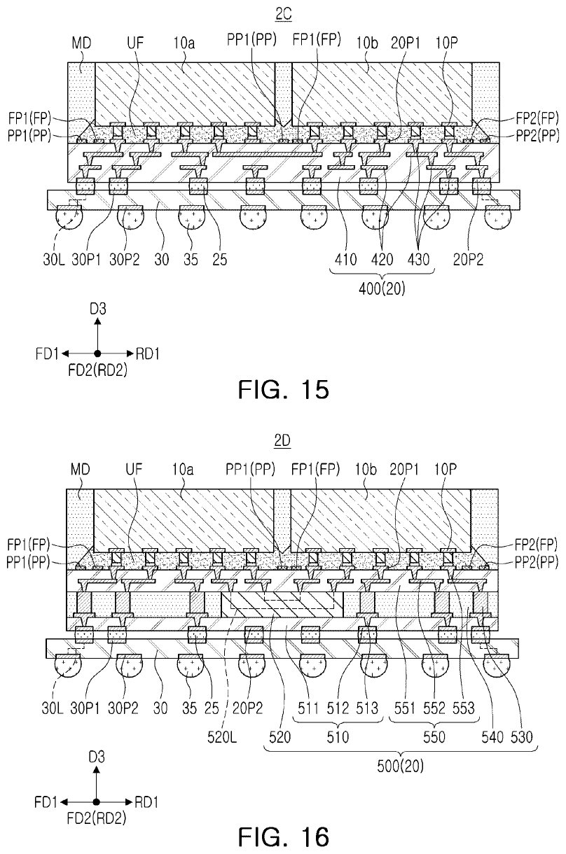

FIG. 15 is a side cross-sectional diagram illustrating a semiconductor package 2C according to some example embodiments.

Referring to FIG. 15, a semiconductor package 2C in some example embodiments may be configured the same as or similar to the example described with reference to FIGS. 1A to 14b, other than the configuration in which the third base chip 400 is included, as compared to the semiconductor packages 2A and 2B in FIGS. 13A and 14A. The third base chip 400 may be understood as a specific example of the base chip 20 described above.

The third base chip 400 may include an insulating layer 410, a redistribution layer 420, and a redistribution via 430. The insulating layer 410 may include an insulating resin. The insulating resin may include a thermosetting resin such as an epoxy resin, a thermoplastic resin such as a polyimide, or a resin impregnated with an inorganic filler, for example, a prepreg, an Ajinomoto build-up film (ABF), FR-4, or bismaleimide-triazine (BT). In some example embodiments, the insulating layer 410 may include a photosensitive resin such as a photo-imageable dielectric (PID). The insulating layer 410 may include a plurality of insulating layers stacked in the vertical direction D3. Depending on processes, a boundary between the plurality of insulating layers may be not be distinct.

The redistribution layer 420 may be disposed on and in the insulating layer 410 and may redistribute connection pads 10P. The redistribution layer 420 may include a metal, for example, copper (Cu), aluminum (Al), silver AG, tin (Sn), gold (Au), nickel (Ni), lead (Pb), titanium (Ti), and/or an alloy thereof. The redistribution layer 420 may include more or fewer number of redistribution layers than the example illustrated in the diagram.

The redistribution via 430 may extend from the insulating layer 410 and may be electrically connected to the redistribution layer 420. The redistribution via 430 may include a metal material, for example, copper (Cu), aluminum (Al), silver AG, tin (Sn), gold (Au), nickel (Ni), lead (Pb), titanium (Ti), and/or an alloy thereof. The redistribution via 430 may be a filled via in which metal material is filled in the via hole or a conformal via in which metal material extends along an internal wall of the via hole.

FIG. 16 is a side cross-sectional diagram illustrating a semiconductor package 2D according to some example embodiments.

Referring to FIG. 16, a semiconductor package 2D in some example embodiments may be configured the same as or similar to the example described with reference to FIGS. 1A to 15 , other than configuration in which a fourth base chip 500 is included, as compared to semiconductor packages 2A and 2B in FIGS. 13A and 14A. The fourth base chip 500 may be understood as a specific example of the base chip 20 described above.

The fourth base chip 500 may include an interconnection chip 520 configured to electrically connect a plurality of semiconductor chips 10a and 10b to each other. For example, the fourth base chip 500 may include a lower redistribution structure 510, an interconnection chip 520, through-electrodes 530, a mold 540, and an upper redistribution structure 550.

The lower redistribution structure 510 may include an insulating layer 511, a redistribution layer 512, and a redistribution via 513. The insulating layer 511 may be formed using a photosensitive resin such as PID. For example, the insulating layer 511 may include a polyimide (PI)-based photosensitive polymer, a polybenzoxazole (PBO)-based photosensitive polymer, a polyhydroxystyrene (PHS)-based photosensitive polymer, a novolak-based photosensitive polymer, or a benzocyclobutene (BCB)-based photosensitive polymer.

The redistribution layer 512 may be disposed on or in the insulating layer 511, and may be electrically connected to the interconnection chip 520, through-electrodes 530, and semiconductor chips 10a and 10b. The redistribution layer 512 may include, for example, copper (Cu), aluminum (Al), silver AG, tin (Sn), gold (Au), nickel (Ni), lead (Pb), titanium (Ti), or alloys thereof. The redistribution layer 512 may include various types of conductive patterns extending in the horizontal direction (X and/or Y).

The redistribution via 513 may penetrate the insulating layer 511 and may be electrically connected to the redistribution layer 512. The redistribution via 513 may include, for example, copper (Cu), aluminum (Al), silver AG, tin (Sn), gold (Au), nickel (Ni), lead (Pb), titanium (Ti), and/or alloys thereof. The redistribution via 513 may be configured as a filled via in which a metal material is filled in the via hole or a conformal via in which a metal material is formed along an internal wall of the via hole.

The interconnection chip 520 may be disposed on the lower redistribution structure 510. The interconnection chip 520 may include an interconnection circuit 520L for electrically connecting the first semiconductor chip 10a to the second semiconductor chip 10b. The interconnection chip 520 may be a semiconductor chip in which the interconnection circuit 520L is formed on a semiconductor substrate, but some example embodiments thereof is not limited thereto.

Through-electrodes 530 may be disposed around the interconnection chip 520 and may be electrically connected to the redistribution layer 512. The through-electrodes 530 may have a post shape extending in the vertical direction D3 corresponding to a thickness of the interconnection chip 520. One surface (e.g., upper surface) of the through-electrodes 530 may be coplanar with one surface (e.g., upper surface) of the mold 540 by a planarization process. The through-electrodes 530 may include copper (Cu), aluminum (Al), silver AG, tin (Sn), gold (Au), nickel (Ni), lead (Pb), titanium (Ti), and/or alloys thereof.

The mold 540 may be disposed between the lower redistribution structure 510 and the upper redistribution structure 550. The mold 540 may be formed to encapsulate the interconnection chip 520 and the through-electrodes 530. The mold 540 may include, for example, a thermosetting resin such as an epoxy resin, a thermoplastic resin such as a polyimide, or a prepreg, ABF, FR-4, BT, EMC, and/or the like, impregnated with an inorganic filler in these resins.

The upper redistribution structure 550 may include an upper insulating layer 551, an upper redistribution layer 552, and an upper redistribution via 553 . The upper insulating layer 551, the upper redistribution layer 552, and the upper redistribution via 553 may be configured substantially the same as the insulating layer 511, the redistribution layer 512, and the redistribution via 513 described above, and accordingly, overlapping descriptions will not be provided. The upper redistribution layer 552 may be connected to the interconnection circuit 520L through the upper redistribution via 553 . A plurality of semiconductor chips 10a and 10b may be electrically connected to the interconnection chip 520 through the upper redistribution layer 552.

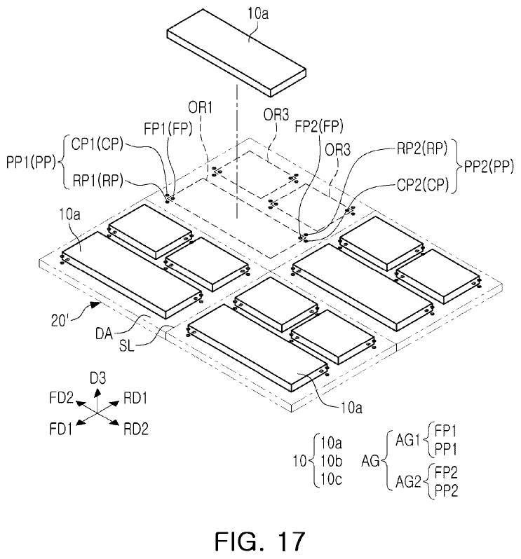

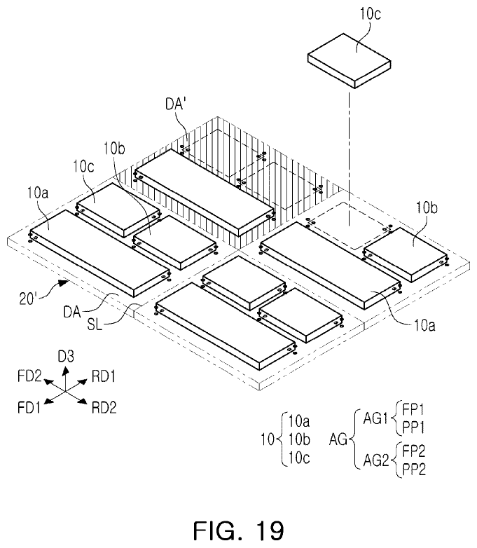

FIGS. 17, 18A to 18D, and 19 are diagrams illustrating a method of manufacturing a semiconductor package according to some example embodiments. FIGS. 17 and 19 illustrate only a portion of a base wafer 20′.

Referring to FIG. 17, a plurality of semiconductor chips 10 may be attached to a base wafer 20′. The base wafer 20′ may include die attachment regions DA, distinguished by scribe lane SL, and upper pads 20P1 arranged in the die attachment regions DA. Also, the base wafer 20′ may further include a pair of alignment pattern groups AG disposed in a diagonal direction in each of overlap regions OR1, OR2, and OR3 in the die attachment regions DA. The alignment pattern groups AG may include reference patterns FP and peripheral patterns PP. The plurality of semiconductor chips 10 may be attached to positions overlapping the reference patterns FP of the corresponding die attachment regions DA. According to some example embodiments, by sensing whether the semiconductor chip 10 overlaps the peripheral patterns PP disposed in each of the die attachment regions DA, a defective unit in which the semiconductor chip 10 among the die attachment regions DA is misaligned may be determined. Here, a defective unit may be defined as a region in which at least a portion of the semiconductor chip 10 and the peripheral patterns PP overlap each other. When the number of non-overlap patterns, which is less or more than the number pre-configured in the first alignment pattern group AG1 and the second alignment pattern group AG2, is sensed, the configuration may be determined as a defective unit. This misalignment determination operation of the semiconductor chip 10 may be performed after the semiconductor chip 10 is attached. For example, the first semiconductor chip 10a may be attached to the first overlap region OR1 in the die attachment regions DA. Whether a defect is present may be more readily determined by recognizing the arrangement relationship between the first semiconductor chip 10a and the alignment pattern groups AG by a vision sensor, and/or the like.

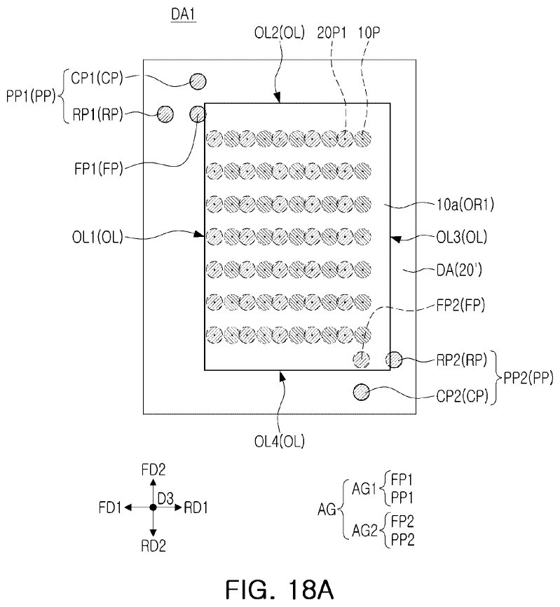

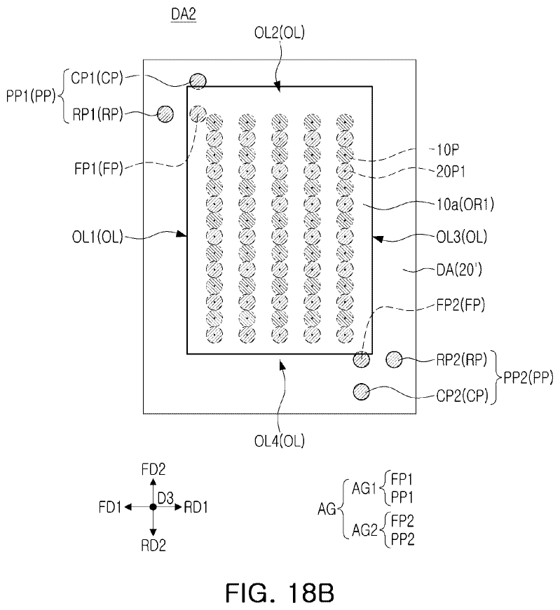

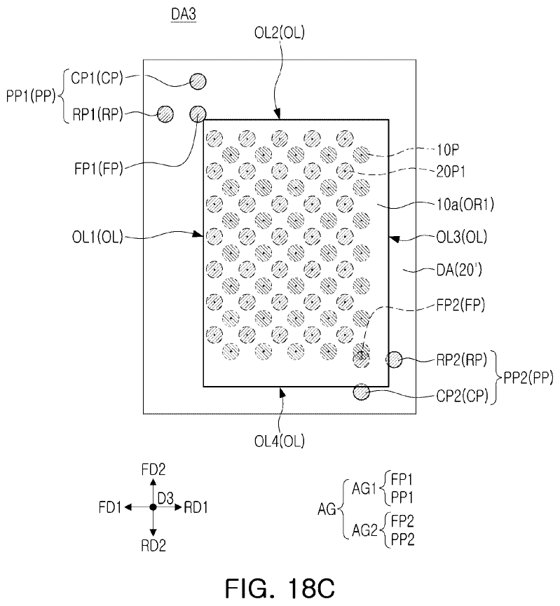

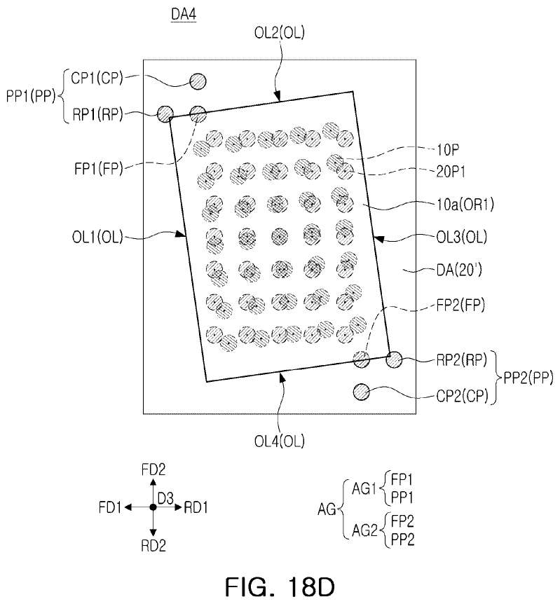

Referring to FIG. 18A, in the first defective unit DA1, the first semiconductor chip 10a may be shifted to the first direction FD1 and RD1 from the designed alignment position. The first semiconductor chip 10a may overlap at least a portion of peripheral pads PP. For example, the first semiconductor chip 10a may overlap at least a portion of the second row pattern RP2. In this case, two non-overlap patterns, the first row pattern RP1 and the first column pattern CP1, in the first alignment pattern group AG1 may be sensed by an alignment pattern sense tool (e.g., vision sensor, and/or the like), and one non-overlap pattern, the second column pattern CP2, in the second alignment pattern group AG2 may be sensed. In some example embodiments, the entirety of the first reference pattern FP1 may be positioned externally of the first overlap region OR1. In this case, three non-overlap patterns, the first reference pattern FP1, the first row pattern RP1 and the first column pattern CP1, may be sensed.

Referring to FIG. 18B, in the second defective unit DA2, the first semiconductor chip 10a may be shifted to the second direction FD2 and RD2 from the designed alignment position. The first semiconductor chip 10a may overlap at least a portion of the peripheral pads PP. For example, the first semiconductor chip 10a may overlap at least a portion of the first column pattern CP1. In this case, by an alignment pattern sense tool (e.g., vision sensor, and/or the like), one non-overlap pattern, the first row pattern RP1, in the first alignment pattern group AG1 may be sensed, and two non-overlap patterns, the second row pattern RP2 and the second column pattern CP2, in the second alignment pattern group AG2 may be sensed. In some example embodiments, the entirety of the second reference pattern FP2 may be positioned externally of the first overlap region OR1. In this case, three non-overlap patterns, the second reference pattern FP2, the second row pattern RP2, and the second column pattern CP2, in the second alignment pattern group AG2 may be sensed.

Referring to FIG. 18C, in the third defective unit DA3, the first semiconductor chip 10a may be shifted from the designed alignment position in the first direction FD1 and RD1 and in the second direction FD2 and RD2. The first semiconductor chip 10a may overlap at least a portion of the peripheral pads PP. For example, the first semiconductor chip 10a may overlap at least a portion of each of the second row pattern RP2 and the second column pattern CP2. In this case, three non-overlap patterns, the first reference pattern FP1, the first row pattern RP1, and the first column pattern CP1, in the first alignment pattern group AG1 may be sensed by an alignment pattern sense tool (e.g., a vision sensor, and/or the like), and zero non-overlap patterns in the second alignment pattern group AG2 may be sensed. In some example embodiments, a portion of the first reference pattern FP1 may be positioned in the first overlap region OR1. In this case, two non-overlap patterns, the first row pattern RP1 and the first column pattern CP1, in the first alignment pattern group AG1 may be sensed.

Referring to FIG. 18D, in the fourth defective unit DA4, the first semiconductor chip 10a may be rotated in a clockwise or counterclockwise direction relative to the designed alignment position. The first semiconductor chip 10a may overlap at least a portion of peripheral pads PP. For example, the first semiconductor chip 10a may overlap at least a portion of each of the first row pattern RP1 and the second row pattern RP1. In this case, by an alignment pattern sense tool (e.g., vision sensor, and/or the like), one non-overlap pattern, the first column pattern CP1, in the first alignment pattern group AG1 may be sensed, and one non-overlap pattern, the second column pattern CP2, in the second alignment pattern group AG2 may be sensed.

Referring to FIG. 19, a subsequent process may be performed on the die attachment regions DA other than the defective unit DA′ in which the first semiconductor chip 10a is misaligned. For example, the second semiconductor chip 10b and the third semiconductor chip 10c may not be attached to the defective unit DA′. The determination of misalignment for each of the second semiconductor chip 10b and the third semiconductor chip 10c may be performed similarly to the inspection for the first semiconductor chip 10a, and when the die attachment region DA in which the second semiconductor chip 10b is misaligned is sensed, the configuration may be determined as a defective unit and the third semiconductor chip 10c may not be attached.

Additionally, based on a die attachment region DA (or a plurality thereof) being determined to be a defective unit DA′, the defective unit DA′ may be discarded or otherwise disposed of after a subsequent singularization operation. For example, after the sensing of the die attachment regions DA and determination as discussed above, the base wafer 20′ may singularize the die attachment regions DA along the scribe lanes SL. The singularization may be performed, for example, using a saw. Further, after singularization, the die attachment regions DA may be one of the semiconductor packages 1, 1a, 1b, etc.

Additionally and/or alternatively, based on a die attachment region DA (or a plurality thereof) being determined to be a defective unit DA', the placement and/or attachment processes may be reviewed to improve the accuracy thereof. For example, noting a position of the defective unit DA′ within the wafer, a temperature of the operating units, a process time, and/or the like and determining a cause of the misalignment.

In some example embodiments, based on determining whether a die attachment region DA in a base wafer 20′ is defective (e.g., is a defective unit DA′), it may be determined that the semiconductor device (or semiconductor device region of a wafer, e.g., the die attachment region DA) is a defective product or a good product. Thereby, functionality of a manufacturing system and/or a manufacturing process of semiconductor devices may be improved, and the technical field of manufacturing semiconductor devices may be improved. Additionally or alternatively, according to some example embodiments, it may be possible to reduce or prevent incorrect pass/fail judgment of a semiconductor device (e.g., semiconductor package 1) due to including a defective die region (for example, due to misalignment). Depending on (or based on) the judgement results, passed semiconductor devices may be sorted out as good products and proceed to other subsequent processes (e.g., subsequent manufacturing processes), and failed semiconductor devices may be discarded, reworked or refurbished, or downgraded.

According to the aforementioned example embodiments, by including reference patterns and peripheral patterns diagonally disposed, a semiconductor package having improved alignment accuracy may be provided.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

While some example embodiments have been illustrated and described above, it will be configured as apparent to those skilled in the art that modifications and variations could be made without departing from the scope of the present disclosure as defined by the appended claims.

What is claimed is:

1. A semiconductor package, comprising:
at least one semiconductor chip including connection pads, and edges defining a front surface, the connection pads on the front surface; and
a base chip including
upper pads electrically connected to the connection pads,
an overlap region, the at least one semiconductor chip and the upper pads being on the overlap region, and
alignment pattern groups including reference patterns in the overlap region, and row patterns and column patterns outside the overlap region,
the overlap region including outlines corresponding to the edges of the at least one semiconductor chip, and vertexes at which the outlines intersect,
the alignment pattern groups including a first alignment pattern group and a second alignment pattern group adjacent to a first vertex and a second vertex opposing each other in a diagonal direction among the vertexes, respectively,
the first alignment pattern group including a first reference pattern, a first row pattern spaced apart from the first reference pattern in a first forward direction, and a first column pattern spaced apart from the first reference pattern in a second forward direction perpendicular to the first forward direction, and
the second alignment pattern group including a second reference pattern, a second row pattern spaced apart from the second reference pattern in a first reverse direction opposite to the first forward direction, and a second column pattern spaced apart from the second reference pattern in a second reverse direction opposite to the second forward direction.

2. The semiconductor package of claim 1, wherein a first distance between the first reference pattern and the first row pattern, a second distance between the first reference pattern and the first column pattern, a third distance between the second reference pattern and the second row pattern, and a fourth distance between the second reference pattern and the second column pattern are a same distance.

3. The semiconductor package of claim 2, wherein the first distance, the second distance, the third distance, and the fourth distance are equal to or less than a minimum distance between the upper pads.

4. The semiconductor package of claim 3, wherein the minimum distance between the upper pads is less than or equal to 50 μm to 0 μm.

5. The semiconductor package of claim 3, wherein the first distance, the second distance, the third distance, and the fourth distance are greater than or equal to 50% to less than or equal to of the minimum distance between the upper pads.

6. The semiconductor package of claim 1, wherein the outlines of the overlap region include a first outline adjacent to the first row pattern, a second outline adjacent to the first column pattern, a third outline adjacent to the second row pattern, and a fourth outline adjacent to the second column pattern.

7. The semiconductor package of claim 6, wherein
a first spacing between the first row pattern and the first outline and a second spacing between the first column pattern and the second outline are different from each other, and
a third spacing between the second row pattern and the third outline and a fourth spacing between the second column pattern and the fourth outline are different from each other.

8. The semiconductor package of claim 7, wherein the first outline, the second outline, the third outline, and the fourth outline have slopes with respect to a corresponding side surface of the base chip.

9. The semiconductor package of claim 6, wherein
a first spacing between the first row pattern and the first outline, and a second spacing between the first column pattern and the second outline are equal to each other, and
a third spacing between the second row pattern and the third outline, and a fourth spacing between the second column pattern and the fourth outline are equal to each other.

10. The semiconductor package of claim 1, wherein the reference patterns, the row patterns, and the column patterns have a same planar shape as a planar shape of the upper pads.

11. The semiconductor package of claim 1, wherein each of the row patterns and the column patterns has a planar shape different from a planar shape of the upper pads.

12. The semiconductor package of claim 11, wherein the reference patterns have a planar shape different from the planar shape of the upper pads.

13. The semiconductor package of claim 11, wherein the reference patterns have a same planar shape as the planar shape of the upper pads.

14. The semiconductor package of claim 11, wherein the planar shape of the row patterns and the planar shape of the column patterns are different.

15. A semiconductor package, comprising:
at least one semiconductor chip including connection pads;
a base chip including an overlap region, the at least one semiconductor chip being on the overlap region, upper pads electrically connected to the connection pads, lower pads electrically connected to the upper pads, alignment pattern groups including reference patterns in the overlap region and peripheral patterns outside the overlap region;
a mold layer covering the at least one semiconductor chip on the base chip; and
external connection bumps below the base chip and electrically connected to the lower pads,
the alignment pattern groups including at least one pair of alignment pattern groups symmetrical to a point of the base chip on a plane.

16. The semiconductor package of claim 15, wherein
the peripheral patterns are spaced apart from the reference patterns in a first direction or a second direction perpendicular to the first direction, and
a distance between the peripheral patterns and the reference patterns in the first direction and the second direction is equal to or smaller than a minimum distance between the upper pads.

17. A semiconductor package, comprising:
at least one semiconductor chip; and
a base chip including an overlap region, the at least one semiconductor chip being on the overlap region, and alignment pattern groups including reference patterns in the overlap region, and peripheral patterns outside the overlap region,
the overlap region including a first vertex and a second vertex opposing each other in a diagonal direction,
the alignment pattern groups including a first alignment pattern group disposed at the first vertex, and a second alignment pattern group at the second vertex,
the first alignment pattern group including at least one first reference pattern, and first peripheral patterns,
the second alignment pattern group including at least one second reference pattern, and second peripheral patterns,
the first peripheral patterns spaced apart from the at least one first reference pattern in a first forward direction and a second forward direction perpendicular to each other, and
the second peripheral patterns spaced apart from the at least one second reference pattern in a first reverse direction and a second reverse direction perpendicular to each other.

18. The semiconductor package of claim 17, wherein
the base chip includes a core substrate, an interconnection structure between the core substrate and upper pads, the interconnection structure including wiring pads, a passivation layer covering the wiring pads, and through-vias penetrating the core substrate and electrically connected to the wiring pads, and
the upper pads penetrate the passivation layer and are connected to the wiring pads.

19. The semiconductor package of claim 18, wherein
the reference patterns and the peripheral patterns are positioned at a same vertical level as the wiring pads, and
the passivation layer covers entire upper surfaces of the reference patterns and the peripheral patterns.

20. The semiconductor package of claim 18, wherein
the interconnection structure further includes dummy pads spaced apart from the wiring pads, and
the reference patterns and the peripheral patterns penetrate the passivation layer, and are connected to the dummy pads, the reference patterns and the peripheral patterns are at a same vertical level as the upper pads.
